(19) United States
(12) Patent Application Publication
(10) Pub. No.: US 2004/0099948 A1
(43) Pub. Date: May 27, 2004

(54) Power semiconductor module with improved insulation strength

(76) Inventor: Thomas Stockmeier, Nurnberg (DE)

Correspondence Address: Andrew F. Young, Esq., Andrew F. Young, P.C., 115 Orchid St., Floral Park, NY, 11001, US

(21) Appl. No.: 10/679,528

(22) Filed: Oct. 6, 2003

(30) Foreign Application Priority Data
Oct. 5, 2002 (DE) DE 102 46 523.1

(51) Int. Cl. H01L 23/34

(52) U.S. Cl. 257/728

(57) ABSTRACT

The invention relates to a power semiconductor module mounted with a base plate or directly mounted on a heat sink, including a packaging, at least one power semiconductor component and at least one substrate provided on both sides with a metallic layer. The at least one power semiconductor component is arranged on the first metallic layer. The second metallic layer is arranged on the second main surface of the substrate. On the first main surface of the substrate an additional conductive layer is arranged around the edge of the substrate and is electroconductively connected with the metallic layer on the second main surface of the substrate.

### PRIORITY CLAIM AND RELATED APPLICATIONS

This application claims foreign priority from DE 102 46 523.1, filed Oct. 5, 2002 and herein incorporates it by reference.

### SELECTED FIGURE FOR PUBLICATION

FIG. 2 is selected for publication on the face of the face of the patent.

### BACKGROUND OF THE INVENTION

1. Field of the Invention

The present invention relates to a power semiconductor module having improved insulation design and strength. More specifically, the present invention relates to a power semiconductor module having a design minimizing defect effects relating to electrical current charge.

2. Description of the Related Art

The invention relates to conventional power semiconductor modules, known, for example, from U.S. Reg. No. 5,466,969. In comparison with discrete power switches (such as sliced cells, TO220), these conventional power semiconductor modules include a base plate, or may alternatively be directly mounted on a heat sink, and offer the great advantage of internal insulation. In Conventionally, this internal insulation was positioned against the base plate or heat sink, accomplished by using ceramic substrates laminated on both sides, combining high insulation strength with good thermal conductivity. These designs allow an efficient configuration of power circuits since they provide not only base insulation and insulation against the environment, but also a functional insulation, insulation of various sections on a structured surface provided with components.

Conventional power semiconductor modules with ceramic substrates are known, for example, from U.S. Pat. No. 5,466,969, EP 0 750 345 A2 and DE 197 00 963 A1. Conventional pressure-contacted assemblies with ceramic substrates are known, for example, from DE 196 51 632 A1. It is also understood from U.S. Reg. No. 5,466,969, that additional components, such as sensors and/or control circuits, may be integrated into the power module.

These conventional embodiments of power semiconductor modules all have in common that they use a ceramic substrate laminated with metal on both sides, produced, for example, by a spinel bond between aluminum oxide (Al₂O₃) and copper oxide according to the direct copper bonding (DCB) method, for example according to EP 0 627 760 A1, or by the active metal brazing (AMB) method. In principle, aluminum or silver are also feasible for use as metallic layers instead of copper. In conjunction with aluminum nitrite (AlN) as a ceramic material, methods are being developed in which an aluminum layer is applied to the ceramic material by means of a sintering process. A further metallic layer such as copper can also be applied subsequently over the aluminum layer. Also known are organic epoxide substrates with metallic layers applied by means of various methods.

Also typical for such power semiconductor modules is a filling with a material such as a monomer of silicon rubber that is polymerized after degasification. This silicon rubber mainly establishes functional isolation. However, it is also applied in the marginal section of the substrate because this is practically easy accomplish, and because the relative dielectric constant of silicon rubber is higher than that of air, which means that the marginal section for establishing base insulation can be narrower.

Generally, the requirements for the insulation strength of base insulation are distinctly higher than the requirements for functional insulation. Thus, the IEC 1287 standard requires the following test voltage for base insulation:

$${U}_{iso , r m s} = \frac{2 \cdot {U}_{m}}{\sqrt{2}} + 1000 V$$

where Uₘ represents the maximum constantly recurring voltage in the circuit. Voltage U_{iso,rms} must be applied for one minute when the component is tested. The insulation capacity of the base insulation depends on how the marginal section of the substrate is configured.

In conventional power semiconductor modules, the two metallic layers on the ceramic surfaces act like a plate condensator with the ceramic as a dielectric between these plates. Typically, the second metallic layer lies on a base plate or a heat sink, and thus usually at ground potential. In conventional power semiconductor modules, this first metallic layer, on which the power semiconductor components are also arranged, lies at least partially on a potential of up to several kilovolt. The metallic layers on both sides of the substrate are not applied right up to the edge to allow this non-metallized marginal section to serve as the air or leakage path of the base insulation of the power semiconductor module.

Unfortunately, during the manufacture of power semiconductor modules, for example in the separation of the individual substrates (specifically ceramic substrates) from a larger entity, detrimental cracks, openings, and microscopic fissures can occur in the marginal section, commonly starting from the edge or separation cite. These manufacture-caused defects of the substrate shorten the path around the ceramic edge between the two metallic layers, and consequently reducing the insulation strength of the entire power semiconductor module in an undefined or unwell-known manner.

The same problem, of reduced insulation strength, also results from air or gas blisters in the filler (usually silicon rubber). For example, these blisters commonly form in the region(s) between the substrate and the packaging. In cases where an adhesive bond exits between the substrate and the packaging, similar problems with a lower relative dielectric constant also occur because air bubbles are common in the adhesive. This type of detrimental gas/air blister (air bubble(s)) always results in a partial reduction of the relative dielectric constant, which correspondingly reduces the partial discharge strength because a detrimental glow discharge may occur.

Referring now to FIG. 1, a conventional power semiconductor module includes a substrate 10 on whose first main surface 10a a first metallic layer 12 is arranged which is conventionally internally structured and serves as the conductive strip for the circuit arrangement. Conventional power semiconductor components are arranged on first metallic layer 12. A second metallic layer 14 is provided on a second main surface 10b of substrate 10. The second layer is not internally structured, and forms a thermoconductive and electroconductive connection with the heat sink 50.

A packaging 40, of insulating plastic, surrounds substrate 10. The same as the substrate 10, this packaging also bears directly on heat sink 50 with the undersides of its side walls. (as shown).

Filling packaging 40 with a silicon rubber 20 accomplish the functional insulation of the power semiconductor module. In this manner, the silicon rubber perfuses the substrate in places where no metallic layer is present. The silicone rubber also perfuses first metallic layer 12 and the power semiconductor components 24 to accomplish their functional insulation. The silicone rubber also contributes to the base insulation, since it perfuses the substrate in the non-metallized marginal section and in an interspace 32 formed between substrate 10 and packaging 40, and hence increases the insulation strength due to the fact that its relative dielectric constant is higher than that of air. As described above, a disadvantage is that in the marginal section, cracks occur in the ceramic or air bubbles can form within the silicon rubber, and some of the volume may be only partially perfused or not at all. These cracks reduce the leakage path between the first and second metallic layer, consequently decreasing the insulation strength. The resultant air bubbles or non-perfused volume lead to glow discharge and thus reduce the insulation strength as well.

Another conventional power semiconductor module includes an adhesive bond 22 between substrate 10 and packaging 40. This conventional design is particularly disadvantageous as air bubbles are present inside the adhesive 22, and between the adhesive and any adjacent components, as well as any defects in the silicone rubber, reduce the insulation strength. Another disadvantage is that, blocked by adhesive bond 22, sections 30 are not perfused by the adhesive, for example between first main surface 10a of substrate 10 and first metallic layer 12. As a consequence of these disadvantages, there is a resultant decrease in insulation strength.

In summary, the problems with commercially available power semiconductor modules include at least the following:

1. Air or gas bubbles formed by the mechanisms noted above between components, prevent adhesive perfusion/contact to a selected surface and a corresponding reduction in insulation strength.

2. Manufacture surface, fissure, edge defects shorten the electrical path from that designed and reduces the insulation strength of the entire power semiconductor module.

3. The predictable functional and base insulation, and their electrical results, are detrimentally affected by each of the mechanisms noted above.

### OBJECTS AND SUMMARY OF THE INVENTION

An object of the present invention is to provide a power semiconductor module with improved insulation strength.

Another object of the present invention is to prevent the effect of defects in the marginal section of the substrate and the effect of designing the arrangement of the substrate in the packaging of the power semiconductor module on the insulation strength of the base insulation and on the partial discharge characteristics.

The present invention relates to a power semiconductor module provided with a base plate or is designed such that it is mounted with the substrate directly on a heat sink. The embodiments noted have at least one substrate surrounded by a packaging. The substrate itself consists of an insulating material such as ceramic or plastic and is at least partially covered on both sides by a metallic layer. In one preferred embodiment, the metallic layer on the first main surface is circuit-friendly so that a desired or a selected function of the power semiconductor module, such as that of a half-bridge, may be functionally realized. For this purpose, at least one power semiconductor component is located on this first metallic layer. On the second main surface of the substrate is also a metallic layer that is generally holohedral (symmetrically or continuously positioned) to the edge or almost to the edge.

At or close to the edge of the first main surface of the substrate of the power semiconductor module, according to one aspect of the present invention, another conductive, preferably metallic layer or an equivalent section aligned with the substrate surface is provided. Hereinafter, the terms layer and section are used synonymously. This layer generally has a specific resistance of less than about 10 kΩ. The layer generally runs around the entire edge of the substrate, and in relation to the first metallic layer of the first main surface, laterally in the direction of the surface, is provided with a clearance such that the base insulation of the power semiconductor module is generally formed by said clearance. The filling of the space between the first and additional conductive layer with an insulating material such as silicon rubber may additionally be taken into account in alternative embodiments. This additional conductive layer of the first main surface of the substrate is electroconductively connected with the second metallic layer of the second main surface, whereby this connection is holohedral or only partial, and therefore this additional metallic layer lies on the potential of the base plate or heat sink.

Thus, the base insulation is not accomplished—as in the conventional art between the first metallic layer and the second metallic layer with a defined edge configuration. In the power semiconductor module according to one aspect of the present invention, the base insulation is accomplished between the first metallic layer and the additional conductive layer.

The present invention relates to a power semiconductor module with a base plate or directly mounted on a heat sink, including a packaging, at least one power semiconductor component and at least one substrate provided on both sides with a metallic layer. The at least one power semiconductor component is arranged on the first metallic layer. The second metallic layer is arranged on the second main surface of the substrate. On the first main surface of the substrate an additional conductive layer is arranged around the edge of the substrate and is electroconductively connected with the metallic layer on the second main surface of the substrate.

According to one embodiment of the present invention there is provided a power semiconductor module, the semiconductor module separably mountable on at least one of a base plate and a heat sink, the power semiconductor module comprising: a packaging member, at least one power semiconductor component, at least one insulating substrate having a first and a second main surface, at least a first metallic layer on the first main surface, at least a second metallic layer on the second main surface, the power semiconductor component on the first metallic layer, at least one additional conductive layer substantially arranged proximate an edge of the substrate, and the at least one additional conductive layer electroconductively connected with the second metallic layer on the second main surface of the substrate, whereby an insulation strength of the module is improved.

According to another embodiment of the present invention, there is provided a power semiconductor module, wherein: the at least one additional conductive layer is at least a first clearance distance from the first metallic layer on the first main surface of the substrate.

According to another embodiment of the present invention, there is provided a power semiconductor module, wherein: the at least one additional conductive layer includes at least one of a metallic layer and a sealing gasket.

According to another embodiment of the present invention, there is provided a power semiconductor module, wherein: the additional conductive layer includes the at least one sealing gasket, and the at least one sealing gasket is an elastic material and is at least one of an electroconductive material and a material having an electroconductive surface portion.

According to another embodiment of the present invention, there is provided a power semiconductor module, wherein: a specific resistance between the sealing gasket and the second metallic layer being less than about 10 kΩ.

According to another embodiment of the present invention, there is provided a power semiconductor module, further comprising: an adhesive bond, and the adhesive bond electroconductively connecting the additional conductive layer with the second metallic layer.

According to another embodiment of the present invention, there is provided a power semiconductor module, wherein: the adhesive bond fixing a portion of the substrate to a portion of the packaging, whereby a strength and manufacturing ease of the module is increased.

According to another embodiment of the present invention, there is provided a power semiconductor module, wherein: a specific resistance of the adhesive bond being less than about 10 kΩ.

According to another embodiment of the present invention, there is provided a power semiconductor module, wherein: at least one through-connection, and the through-connection electroconductively connecting the at least one additional conductive layer with the second metallic layer.

According to another embodiment of the present invention, there is provided a power semiconductor module, wherein: the through-connection is a metallic through-connection.

According to another embodiment of the present invention, there is provided a power semiconductor module, further comprising: at least one sealing gasket, and the at least sealing gasket being the additional conductive layer and integrally electroconductively connecting the first metallic layer with the second metallic layer.

According to another embodiment of the present invention, there is provided a power semiconductor module, wherein: the at least one sealing gasket sealingly joins portions of the first metallic surface, the second metallic surface, and the substrate with portions of the packaging member, whereby an assembly reliability of the module is increased.

According to another embodiment of the present invention, there is provided a power semiconductor module, wherein: a specific resistance of the electroconductive connection between the at least one additional conductive layer and the second metallic layer is less than about 10 kΩ.

According to another embodiment of the present invention, there is provided a power semiconductor module, further comprising: at least one further conductive layer on the first main surface of the substrate between the first metallic layer and the at least one additional conductive layer.

According to another embodiment of the present invention, there is provided a power semiconductor module, wherein: the at least one further conductive layer arranged substantially parallel the additional conductive layer, whereby the at least one further conductive layer are effective as field rings enabling a spreading equipotential lines between the first metallic layer and the additional conductive layer.

According to another embodiment of the present invention there is provided a power semiconductor module, comprising: a packaging member, at least one power semiconductor component, at least one insulating substrate having a first and a second main surface, at least a first metallic layer on the first main surface, at least a second metallic layer on the second main surface, the power semiconductor component on the first metallic layer, at least one additional conductive layer substantially arranged proximate an edge of the substrate, the at least one additional conductive layer electroconductively connected with the second metallic layer on the second main surface of the substrate, the at least one additional conductive layer at least a first clearance distance from the first metallic layer on the first main surface of the substrate, and the at least one additional conductive layer includes at least one of a metallic layer and a sealing gasket.

According to another embodiment of the present invention there is provided a power semiconductor module, comprising: the at least one sealing gasket is an elastic material and is at least one of an electroconductive material and a material having an electroconductive surface portion.

According to another embodiment of the present invention there is provided a power semiconductor module, comprising: the electroconductive connection between the one additional layer and the second metallic layer is at least one of a through-connection passing through a portion of the substrate and a side-connection passing around an edge of the substrate.

According to another embodiment of the present invention, there is provided a method of manufacturing a power semiconductor module, comprising the steps of: forming a first metallic layer on a first main surface of a substrate, forming a second metallic layer on a second main surface of the substrate, positioning at least one power semiconductor component on the first metallic surface distal from an edge of the substrate, positioning a packaging member spaced from and proximate to the edge of the substrate, forming at least one additional conductive layer on the first main surface of the substrate proximate the edge of the substrate and spaced from the first metallic layer, and electroconductively connecting the at least one additional layer to the second metallic layer, thereby improving an insulation strength of the module.

According to another embodiment of the present invention, there is provided a power semiconductor module, mounted on at least one of a base plate and a heat sink, the power semiconductor module comprising: a packaging, at least one power semiconductor component, at least one insulating substrate provided on a first side with a first metallic layer and on a second side with a second metallic layer, the at least one power semiconductor component on the first metallic layer, the first metallic layer on a first main surface of the substrate and the second metallic layer is on the second main surface of the substrate, and at least a one additional conductive layer arranged proximate an edge of the substrate and electroconductively connected with the second metallic layer on the second main surface of the substrate, thereby improving an insulation strength of the power semiconductor module.

According to another embodiment of the present invention, there is provided a power semiconductor module, wherein: the at least one additional conductive layer is structurally identical with the first and the second metallic layers, and the at least one conductive layer being formed by the same manufacturing technique as the first and the second metallic layers.

According to another embodiment of the present invention, there is provided a power semiconductor module, wherein: the first metallic layer is internally structured to enable a circuit-friendly design of the power semiconductor module.

According to another embodiment of the present invention, there is provided a power semiconductor module, wherein: the electroconductive connection between the at least one additional conductive layer is at least one local through-connection between the second metallic and the at least one conductive layer, and the at least one local through-connection being proximate the edge.

According to another embodiment of the present invention, there is provided a power semiconductor module, wherein: the electroconductive connection between the at least one additional conductive layer is established by an electroconductive adhesive which fixes the substrate in the packaging.

According to another embodiment of the present invention, there is provided a power semiconductor module, wherein: the electroconductive connection between the at least one additional conductive layer and the second metallic layer is a sealing gasket, and the sealing gasket being made from at least one of an elastic and an electroconductive material and a material provided with an electroconductive surface.

According to another embodiment of the present invention, there is provided a power semiconductor module, further comprising: at least one further conductive layer between the first metallic layer and the additional conductive layer, and the at least one further conductive layer arranged substantially parallel to the additional conductive layer, whereby the at least one further conductive layer is effective as a field ring.

According to another embodiment of the present invention, there is provided a power semiconductor module, wherein: a specific resistance of the electroconductive connection between the at least one additional conductive layer and the second metallic layer is less than about 10 kΩ.

The above, and other objects, features and advantages of the present invention will become apparent from the following description read in conduction with the accompanying drawings, in which like reference numerals designate the same elements.

### BRIEF DESCRIPTION OF THE DRAWINGS

FIG. 1 is a sectional view of a conventional semiconductor module.

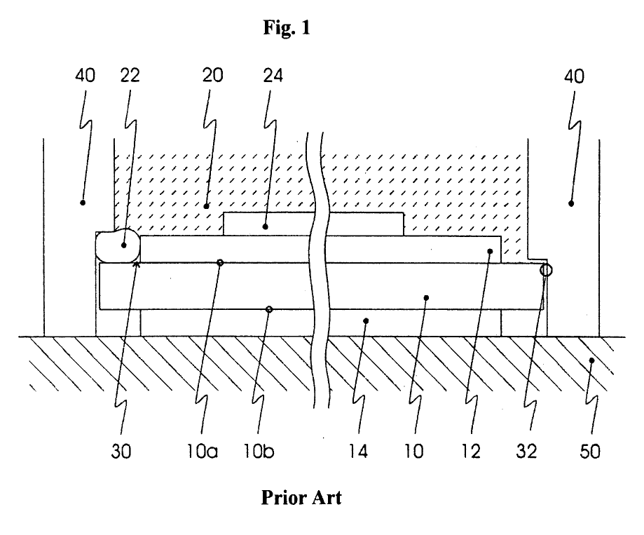

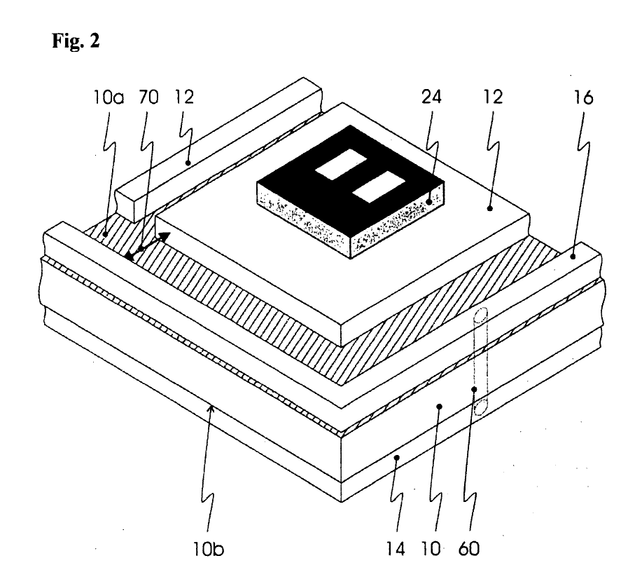

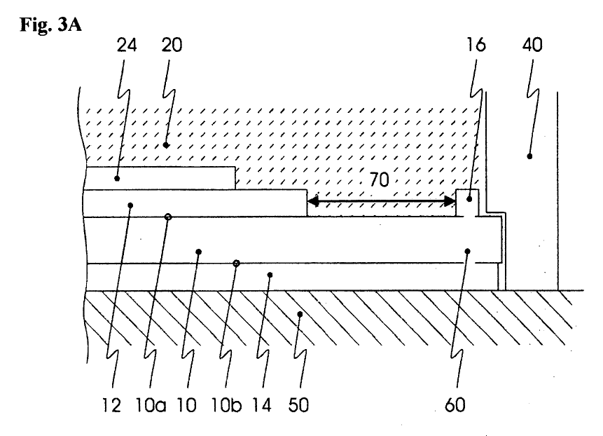

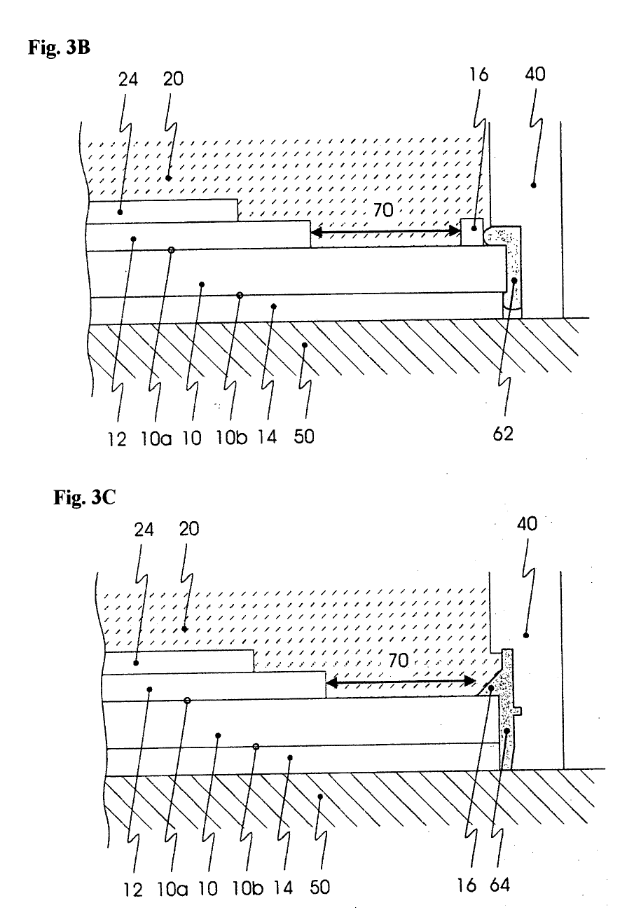

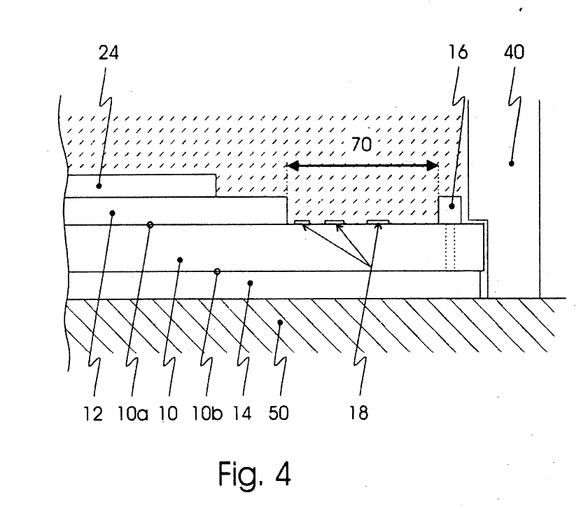

FIG. 2 is a prospective view of a portion of a power semiconductor module according to the invention.

FIG. 3A is a second embodiment of a power semiconductor module according to an embodiment of the present invention.

FIG. 3B is a third embodiment of a power semiconductor module according to the present invention.

FIG. 3C is a fourth embodiment of a power semiconductor module according to the present invention.

FIG. 4 is a second embodiment of a power semiconductor module according to the present invention.

### DETAILED DESCRIPTION OF THE PREFERRED EMBODIMENTS

In coping with the problems noted above, the present invention provides a power semiconductor module with improved insulation design and other features as noted herein. While the present invention is believed fully disclosed herein, the contents of the priority document DE 102 46 523.1, are herein incorporated as a supporting reference.

Referring now to FIG. 2, one embodiment of the present invention shows a substrate for a power semiconductor module including a ceramic layer 10 on whose first main surface 10a a first metallic layer 12 is arranged and on whose second main surface 10b a second metallic layer 14 is arranged. The first metallic layer 12 serves as carrier for the power circuit and thus of the power semiconductor components 24 and has its own internal structure. The second metallic layer 14 is in thermal and electroconductive contact with a base plate or directly with heat sink and is without internal structure.

A marginal section of the ceramic substrate layer 10 of the power semiconductor module according to the invention is provided with an additional conductive layer 16 on the first main surface 10a and conductively connected via a through-connection 60 with the second metallic layer 14 on the second main surface 10b of the substrate 10. In the present embodiment shown, the additional conductive layer 16 is provided with a clearance 70 of about 4 mm from the internally structured first metallic layer 12, which ensures the base insulation of the power semiconductor module after the filling with silicon rubber 20. As is shown below, the present invention envisions clearances 70 selected by a manufacture depending upon a number of factors, including the materials selected, as will be discussed. As such, it will be understood that having envisioned the present invention multiple alternative embodiments are available selectable and adaptable to a wide variety if design situations, material selections, electrical/charge requirements etc.

The following Table 1 includes some typical parameters for the above-named components of the power semiconductor module according to one aspect of the present invention. It should be understood, that Table 1 is illustrative in nature, is not restrictive of the entire invention, merely an embodiment, and alternative materials, thicknesses, manufacturing methods, and dielectric constants are included as embodiments herein without departing from the scope of the invention.

TABLE 1

| | | | Relative dielectric |
|---|---|---|---|
| Layer | Material | Thickness | constant ε/εᵥ |
| First Metallic Layer 12 of | Copper | 0.3 mm | — |
| the first surface 4 | | | |
| Substrate 10 | Aluminum | 1.0 mm | 9.0 |
| | Nitrite | | |
| Second Metallic Layer 14 | Copper | 0.3 mm | — |
| Ambient Medium 20 | Silicon | — | 2.9 |
| | Rubber | | |
| Additional Metallic Layer 16 | Copper | 0.3 mm | — |

Referring now to FIGS. 3A-3C additional alternative embodiments of the present invention for a power semiconductor module are provided. Similar to the above described, the present embodiments include a substrate 10 on whose first main surface 10a a first metallic layer 12 is arranged which is internally structured and serves as conductive strip for the circuit arrangement. The power semiconductor components 24 are arranged on the first metallic layer 12. The second metallic layer 14 of the second main surface 10b of the substrate 10 is not internally structured and is provided with a thermoconductive and electroconductive connection with the heat sink 50, as noted above (not shown here). A packaging 40 of insulating plastic arranged on the heat sink 50 surrounds the substrate 10.

The functional insulation of the power semiconductor module is accomplished by filling the packaging 40 with a selected silicon rubber 20. For the base insulation, the power semiconductor module is provided with an additional conductive layer 16 arranged on the first main surface 10a of substrate 10. Advantageously, this additional conductive layer 16 is preferably (but is not required to be) made or produced by the same manufacturing process and simultaneously with the first metallic layer 12. The DCB method or the AMB method (described above) are particularly suited for that purpose. The additional conductive layer 16 is arranged around the entire periphery of the selectively shaped substrate 10 and is electrocunductively connected with the second metallic layer 14 on the second main surface 10b of substrate 10. Consequently, this additional conductive layer 16 lies on the potential of the heat sink 50. It should be understood, that the additional conductive layer 16 is positionably adaptable to suit the purposes and geometries of the substrate 10, first main surface 10a, second metallic layer 14, and other features of a power semiconductor design. The insulation strength of the power semiconductor module therefore depends on the selected clearance 70 between those parts of the metallic layer 12 that lie on high potential and the additional metallic layer 16. Thus, it is envisioned that a designer applying the present invention to a particular design may position the elements of the present invention other than as depicted in the herein without departing from the spirit and scope of the invention.

Advantageously, it is envisioned that this section (clearance 70) is filled with silicon rubber 20 (or other suitable material) which may also provides the functional insulation of the power semiconductor module. While alternative embodiments of the present invention are envisioned without the use of silicon rubber (or other selected material capable of providing the same function), the latter has a higher relative dielectric constant than air, which means that the clearance 70 can have smaller dimensions than would be possible without filling. The clearance 70 is selected and designed such that the above-named base insulation requirements of the power semiconductor module are met.

In one embodiment of the present invention, the additional conductive layer 16 is uninterrupted along its entire length around the edge of the substrate 10. However, the additional conductive layer 16 may have selected small interruptions—depending on the specific design of the power semiconductor module—without adversely affecting the functionality. In an alternative embodiment of the present invention, where additional conductive layer 16 includes small interruptions, each partial section of the additional conductive layer 16 is provided with an electroconductive connection with the second metallic layer 14.

FIG. 3A shows an embodiment of the electroconductive connection between the additional conductive layer 16 and the second metallic layer 14. For this purpose, the substrate 10 is provided with holes (as shown) in which a preferably metallic through-connection 60 is arranged between these two layers.

FIG. 3A shows another embodiment of the electrical connection between the additional conductive layer 16 and the second metallic layer 14. For his purpose, an adhesive bond 62 is arranged such that it connects substrate 10 with the packaging 40 on at least one side and forms an electroconductive connection between the marginal section of the additional conductive layer 16 (as shown) and the second metallic layer 14, whereby the objective can already be achieved when the specific resistance of this electroconductive adhesive bond 62 is less than up to about 10 kΩ.

FIG. 3C shows another embodiment of a power semiconductor module according to the invention, whereby the additional conductive layer 16 is formed by the connection with the second metallic layer 14 itself. In this embodiment, the packaging 40 is provided with an elastic sealing gasket 64 whose material has a specific resistance of less than up to about 10 kΩ. In this embodiment, the additional conductive layer 16 is formed by that part of sealing gasket 64 which is arranged flush on the first main surface 10a of the substrate 10. Alternative geometric positions for sealing gasket 64 are envisioned in alternative embodiments of the present invention allowing a manufacturer to adapt to various semiconductor module design requirements.

In viewing the geometry of sealing gasket 64 and it should be understood that gasket 64 may be geometrically joined with packaging 40 as shown or not depending upon a manufacturers needs. In this embodiment, this geometric joining provides an additional advantage of a mechanical joint while aiding in mechanical positioning of module components during manufacturer. Alternative shapes for sealing gasket 64, including the use of non-continuous sealing gasket elements (not shown), are envisioned allowing a user to adopt the principals of the present invention to a particular need.

Referring now to FIG. 4, another embodiment of the present invention provides, in addition to the additional conductive layer 16 in the clearance section 70 field, one or more field rings 18 are arranged between this and the first metallic layer 12. These one-or-more field rings 18 consist of a plurality of conductive layers arranged generally parallel to the additional conductive layer 16. Advantageously, these field rings 16 are not as high as layers (12, 14, 16), since these field rings 16 must have a finer structure than the other layers. The AMB method has proven to be a preferred manufacturing method for making the layers and the field rings, since the AMB method allows the separation of thin metallic layers.

The field rings 16 operate to cause the spreading out of the equipotential lines formed in the section 70 between first metallic layer 12 and the additional conductive layer 16, thus further improving the partial discharge strength if arranged appropriately according to the present invention.

Employing the present invention, one skilled in the art should readily envision that the use of field rings 18 is readily adapted to situations where the additional conductive layer 16 is not continuous or where various module components and their positions require a particular geometry not depicted in the present FIG. 4. In this manner, the present invention allows ready adaptability to alternative embodiments to achieve a manufacturer's requirements while maintaining the benefits described above.

It should be understood, that the definitions of the technical terms used herein are found in Chapter 1 of König, Rao: “Teilentladungen in Betriebsmitteln der Energietechnik” [Partial Discharges In Operating Elements Used In Energy Technology”], VDE Verlag, 1993, ISBN 3-8007-1764-6. This reference should be used to understand the ordinary meaning of the technical terms where their meets and bounds, as applied here, are not otherwise discussed or enlivened by the disclosure to one skilled in the art.

Although only a single or few exemplary embodiments of this invention have been described in detail above, those skilled in the art will readily appreciate that many modifications are possible in the exemplary embodiment(s) without materially departing from the novel teachings and advantages of this invention. Accordingly, all such modifications are intended to be included within the spirit and scope of this invention as defined in the following claims.

In the claims, means- or step-plus-function clauses are intended to cover the structures described or suggested herein as performing the recited function and not only structural equivalents but also equivalent structures. Thus, for example, although a nail, a screw, and a bolt may not be structural equivalents in that a nail relies entirely on friction between a wooden part and a cylindrical surface, a screw's helical surface positively engages the wooden part, and a bolts head and nut compress opposite sides of at least one wooden part, in the environment of fastening, a nail, a screw, and a bolt may be readily understood by those skilled in the art as equivalent structures.

Having described at least one of the preferred embodiments of the present invention with reference to the accompanying drawings, it is to be understood that the invention is not limited to those precise embodiments, and that various changes, modifications, and adaptations may be effected therein by one skilled in the art without departing from the scope or spirit of the invention as defined in the appended claims.

What is claimed is:

1. A power semiconductor module, said semiconductor module separably mountable on at least one of a base plate and a heat sink, said power semiconductor module comprising:
a packaging member;
at least one power semiconductor component;
at least one insulating substrate having a first and a second main surface;
at least a first metallic layer on said first main surface;
at least a second metallic layer on said second main surface;
said power semiconductor component on said first metallic layer;
at least one additional conductive layer substantially arranged proximate an edge of said substrate; and
said at least one additional conductive layer electroconductively connected with said second metallic layer on said second main surface of said substrate, whereby an insulation strength of said module is improved.

2. A power semiconductor module, according to claim 1, wherein:
said at least one additional conductive layer is at least a first clearance distance from said first metallic layer on said first main surface of said substrate.

3. A power semiconductor module, according to claim 1, wherein:
said at least one additional conductive layer includes at least one of a metallic layer and a sealing gasket.

4. A power semiconductor module, according to claim 3, wherein:
said additional conductive layer includes said at least one sealing gasket; and
said at least one sealing gasket is an elastic material and is at least one of an electroconductive material and a material having an electroconductive surface portion.

5. A power semiconductor module, according to claim 4, wherein:
a specific resistance between said sealing gasket and said second metallic layer being less than about 10 kΩ.

6. A power semiconductor module, according to claim 1, further comprising:
an adhesive bond; and
said adhesive bond electroconductively connecting said additional conductive layer with said second metallic layer.

7. A power semiconductor module, according to claim 6, wherein:
said adhesive bond fixing a portion of said substrate to a portion of said packaging, whereby a strength of said module is increased.

8. A power semiconductor module, according to claim 6, wherein:
a specific resistance of said adhesive bond being less than about 10 kΩ.

9. A power semiconductor module, according to claim 1, further comprising:
at least one through-connection; and
said through-connection electroconductively connecting said at least one additional conductive layer with said second metallic layer.

10. A power semiconductor module, according to claim 9, wherein:
said through-connection is a metallic through-connection.

11. A power semiconductor module, according to claim 1, further comprising:
at least one sealing gasket; and
said at least sealing gasket being said additional conductive layer and integrally electroconductively connecting said first metallic layer with said second metallic layer.

12. A power semiconductor module according to claim 11, wherein:
said at least one sealing gasket sealingly joins portions of said first metallic surface, said second metallic surface, and said substrate with portions of said packaging member, whereby an assembly reliability of said module is increased.

13. A power semiconductor module, according to claim 1, wherein:
a specific resistance of said electroconductive connection between said at least one additional conductive layer and said second metallic layer is less than about 10 kΩ.

14. A power semiconductor, according to claim 1, further comprising:
at least one further conductive layer on said first main surface of said substrate between said first metallic layer and said at least one additional conductive layer.

15. A power semiconductor, according to claim 14, wherein:
said at least one further conductive layer arranged substantially parallel said additional conductive layer, whereby said at least one further conductive layer are effective as field rings enabling a spreading equipotential lines between said first metallic layer and said additional conductive layer.

16. A power semiconductor module, comprising:
a packaging member;
at least one power semiconductor component;
at least one insulating substrate having a first and a second main surface;
at least a first metallic layer on said first main surface;
at least a second metallic layer on said second main surface;
said power semiconductor component on said first metallic layer;
at least one additional conductive layer substantially arranged proximate an edge of said substrate;
said at least one additional conductive layer electroconductively connected with said second metallic layer on said second main surface of said substrate;
said at least one additional conductive layer at least a first clearance distance from said first metallic layer on said first main surface of said substrate; and
said at least one additional conductive layer includes at least one of a metallic layer and a sealing gasket.

17. A power semiconductor module, according to claim 16, wherein:
said at least one sealing gasket is an elastic material and is at least one of an electroconductive material and a material having an electroconductive surface portion.

18. A power semiconductor module, according to claim 16, wherein:
said electroconductive connection between said one additional layer and said second metallic layer is at least one of a through-connection passing through a portion of said substrate and a side-connection passing around an edge of said substrate.

19. A method of manufacturing a power semiconductor module, comprising the steps of:
forming a first metallic layer on a first main surface of a substrate;
forming a second metallic layer on a second main surface of said substrate;
positioning at least one power semiconductor component on said first metallic surface distal from an edge of said substrate;
positioning a packaging member spaced from and proximate to said edge of said substrate;
forming at least one additional conductive layer on said first main surface of said substrate proximate said edge of said substrate and spaced from said first metallic layer; and
electroconductively connecting said at least one additional layer to said second metallic layer, thereby improving an insulation strength of said module.

20. A power semiconductor module, mounted on at least one of a base plate and a heat sink, said power semiconductor module comprising:
a packaging;
at least one power semiconductor component;
at least one insulating substrate provided on a first side with a first metallic layer and on a second side with a second metallic layer;
said at least one power semiconductor component on said first metallic layer;
said first metallic layer on a first main surface of said substrate and said second metallic layer is on said second main surface of said substrate, and
at least a one additional conductive layer arranged proximate an edge of said substrate and electroconductively connected with said second metallic layer on said second main surface of said substrate, thereby improving an insulation strength of said power semiconductor module.

21. A power semiconductor module, according to claim 1, wherein:
said at least one additional conductive layer is structurally identical with said first and said second metallic layers; and
said at least one conductive layer being formed by the same manufacturing technique as said first and said second metallic layers.

22. A power semiconductor module, according to claim 1, wherein:
said first metallic layer is internally structured to enable a circuit-friendly design of said power semiconductor module.

23. A power semiconductor module, according to claim 1, wherein:
said electroconductive connection between said at least one additional conductive layer is at least one local through-connection between said second metallic and said at least one conductive layer; and
said at least one local through-connection being proximate said edge.

24. A power semiconductor module, according to claim 1, wherein:
said electroconductive connection between said at least one additional conductive layer is established by an electroconductive adhesive which fixes said substrate in said packaging.

25. A power semiconductor module, according to claim 1, wherein:
said electroconductive connection between said at least one additional conductive layer and said second metallic layer is a sealing gasket; and
said sealing gasket being made from at least one of an elastic and an electroconductive material and a material provided with an electroconductive surface.

26. A power semiconductor module, according to claim 1, further comprising:
at least one further conductive layer between said first metallic layer and the additional conductive layer; and
said at least one further conductive layer arranged substantially parallel to the additional conductive layer, whereby said at least one further conductive layer is effective as a field ring.

27. A power semiconductor module, according to claim 1, wherein:
a specific resistance of said electroconductive connection between said at least one additional conductive layer and said second metallic layer is less than about 10 kΩ.
